(19) United States
(12) Patent Application Publication
(10) Pub. No.: US 2024/0347427 A1
(43) Pub. Date: Oct. 17, 2024

(54) LEADFRAME COMPRISING A LEAD WITH AN ELEVATION FOR INCREASING MECHANICAL ROBUSTNESS AND A SEMICONDUCTOR PACKAGE

(71) Applicant: Infineon Technologies AG, Neubiberg (DE)

(72) Inventors: Edward FÜRGUT, Dasing (DE); Teck Sim LEE, Melaka (MY); Guey Yong CHEE, Melaka (MY); Thai Kee GAN, Melaka (MY); Thomas BEMMERL, Schwandorf (DE); Markus FINK, Zell (DE)

(73) Assignee: Infineon Technologies AG, Neubiberg (DE)

(21) Appl. No.: 18/598,163

(22) Filed: Mar. 7, 2024

(30) Foreign Application Priority Data
Apr. 17, 2023 (DE) 10 2023 109 583.8

(51) Int. Cl. H01L 23/495; H01L 23/00; H01L 25/07

(52) U.S. Cl. CPC H01L 23/49555; H01L 23/49537; H01L 23/49562; H01L 24/08; H01L 25/072; H01L 2224/08221; H01L 2924/1203; H01L 2924/13055; H01L 2924/13091

(57) ABSTRACT

A leadframe is disclosed. In one example, the leadframe comprises a die pad and a first lead comprising an inner portion and an external portion. The first lead comprises at least one elevation portion extending over a predetermined length in a longitudinal or lateral direction of the first lead. The external portion is configured to be used for external electrical connection. In another example, a semiconductor package having a leadframe is disclosed.

### CROSS-REFERENCE TO RELATED APPLICATION

This Utility patent application claims priority to German Patent Application No. 10 2023 109 583.8 filed Apr. 17, 2023, which is incorporated herein by reference.

### TECHNICAL FIELD

The present disclosure is related to a leadframe and a semiconductor package.

### BACKGROUND

Discrete semiconductor power packages are continuously developed further in the direction of higher efficiency and output power. A decisive factor here is increasing the current-carrying capacity of the packages to be developed. In new applications like “green energy” e.g. solar modules, ESS (energy storage systems), electric vehicle charging, the product lifetime is also limited by power cycling robustness, therefore high current in combination with high power cycling is offering new business potentials.

In particular wide bandgap devices such as SiC and GaN transistor dies can achieve far higher current densities compared to standard Si devices. Therefore, either smaller dies can be used with the same current output, or a higher current output can be achieved with the same size of the die. As a consequence, the interconnections of the device (wires, clips, etc.) must also carry a higher current, which can be limiting for some devices.

One way to increase the current carrying capacity of the package is to increase the number of electrical connections between two elements, for example, increase the number of bonding wires between the source pad of a semiconductor die and the source lead(s) in a semiconductor package. However, since this increased number of connections usually requires more space, problems can arise at another point, particularly of a mechanical nature, for example, more bonding wires for source connection will reduce the space for other leads, especially for drain lead of the package, especially when the size of the package needs to be remained or at least cannot increase significantly. Another cause comes from packages having multiple dies, for example having multiple power dies and/or logic dies. Even, for each die, the number of connections between this die and the leads does not increase, the total connection can increase significantly. When the form factor of the package cannot increase significantly accordingly, at least some leads of the package will be narrowed. There also other possible reasons to reduce the width of some leads.

For these and other reasons there is a need for the present disclosure.

### SUMMARY

In the development of semiconductor power transistors, as already mentioned above there is in general a trend to increase the number of bond wires and/or width of clips connecting a power pad, e.g., a source pad and/or a drain connector, to the external source/drain leads. This can result in a reduced space for other external pins, like the drain pin, gate pin, current sensor pin, etc., therefore the width of at least one these pins has to be narrowed. This can result in reduced manufacturing robustness, which can introduce a high risk of bending or vibration during e.g., die attachment process, wire bonding process, molding process, etc. Thus, one motivation of the present disclosure is to increase the mechanical robustness of at least one of these pins, for example when it connects and supports the die pad or accommodates bonding wires or clips or other components.

A first aspect of the present disclosure is related to a leadframe comprising a die pad, a first lead comprising an inner portion and an external portion, wherein the first lead comprises at least one elevation portion extending over a predetermined length in a longitudinal or lateral direction of the first lead, wherein the external portion is configured to be used for external electrical connection.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 shows a top view on an example of a leadframe having two elevations on an inner portion and portion of the tiebar section of the first lead.

FIG. 2 comprises FIGS. 2A, 2B and 2C and shows two top views on two different chocolate bar leadframes (A, B) and a top view on one of the individual leadframes (C).

FIG. 3 shows a top view on an example of a leadframe having two elevations on a first lead which is not connected with the die pad.

FIG. 4 comprises FIG. 4A and FIG. 4B and shows a top view (A) and a perspective view from the front (B) on an example of a leadframe having a rectangular shaped elevation only on a portion of the tiebar section of the first lead.

FIG. 5 comprises FIG. 5A to FIG. 5C and shows a top view on a semiconductor package (A), a perspective view (B), and another perspective view (C) on a lead frame contained in the semiconductor package, this example of a leadframe having a rectangular shaped elevation on the down-set section and the complete tiebar section of the first lead.

FIG. 6 comprises FIG. 6A and FIG. 6B and shows a top view on a semiconductor package (A) and a perspective view from the front (B) on a leadframe contained in the semiconductor package, this example of a leadframe having a rectangular shaped elevation only on the complete tiebar section of the first lead.

FIG. 7 comprises FIG. 7A to FIG. 7D and shows a top view on a semiconductor package (A), a perspective view (B), a cross-sectional view (C) and another perspective view from the front (D) on a lead frame contained in the semiconductor package, this example of a leadframe having a first rectangular shaped elevation on a portion of the down-set section and a second elevation on a portion of the tiebar section of the first lead.

FIG. 8 comprises FIG. 8A and FIG. 8B and shows a top view on a semiconductor package (A) and a perspective view from the front (B) on a leadframe contained in the semiconductor package, this example of a leadframe having a rectangular shaped elevation only on a portion of the second lead.

FIG. 9 comprises FIG. 9A and FIG. 9B and shows a top view on a semiconductor package (A) and a perspective view from the front (B) on a leadframe contained in the semiconductor package, this example of a leadframe having a rectangular shaped elevation only on a portion of the dambar section of the first lead.

FIG. 10 comprises FIG. 10A to FIG. 10C and shows a top view on an intermediate product of the semiconductor package fabrication (A), a perspective view from the side (B) on a portion of the leadframe contained in the intermediate product, and an enlarged perspective view from the side (C) on the portion of the finished leadframe, this example of a leadframe having a rectangular shaped elevation extending laterally on the dambar section of the first lead.

FIG. 11 comprises FIG. 11A to FIG. 11C and shows a perspective view on a semiconductor package (A), a perspective view from the front (B), and another perspective view from slightly below (C) on a lead frame contained in the semiconductor package, this example of a leadframe having a bent up member on an edge portion of the inner portion.

FIG. 12 comprises FIG. 12A to FIG. 12C and shows a top view on a semiconductor package (A), a perspective view from the front of a leadframe contained in the semiconductor package (B), and another perspective view (C) from the front on a portion of the lead frame, this example of a leadframe having a V shaped elevation on a portion of the inner portion of the first lead.

FIG. 13 shows a top view on a gate driver die, wherein the preferred locations for the placement of the elevations are shown.

FIG. 14 shows a top view on section of a typical IPM module in which elevations are provided on particular leads.

FIG. 15 shows a top view on section of a typical IPM module in which elevations are provided on particular leads.

### DESCRIPTION

A first aspect of the present disclosure is related to a leadframe comprising a die pad, a first lead comprising an inner portion and an external portion, wherein the first lead comprises at least one elevation portion extending over a predetermined length in a longitudinal or lateral direction of the first lead, wherein the external portion is configured to be used for external electrical connection.

According to an embodiment of the leadframe of the first aspect, the leadframe further comprises a second lead having an inner portion and an external portion, wherein the external portion is configured to be used for external electrical connection.

According to an embodiment of the leadframe of the first aspect, the elevation is produced by a deformation of the first lead, in particular by a coining exerted in a direction perpendicular to the longitudinal direction of the first lead.

According to an embodiment of the leadframe of the first aspect, the elevation portion is arranged on the inner portion, wherein the inner portion is to be embedded into an encapsulant.

According to an embodiment of the leadframe of the first aspect, wherein the external portions of the first and the second leads respectively comprise a dambar portion, wherein the elevation of the first lead is arranged on the dambar portion of the first lead (12).

According to an embodiment of the leadframe of the first aspect, the first lead is physically connected to the die pad.

According to an embodiment of the leadframe of the first aspect, the inner portion comprises a down-set portion.

According to an embodiment of the leadframe of the first aspect, the inner portion of the first lead is not physically connected to the die pad.

According to an embodiment of the leadframe of the first aspect, the inner portion is configured to be connected to a bonding wire or a passive component.

According to an embodiment of the leadframe of the first aspect, the elevation is provided on both the inner portion and the connection portion.

According to an embodiment of the leadframe of the first aspect, the elevation comprises any one of a rectangular shape or a V shape in a lateral cross section, and/or a bent up member on an edge of the connection portion.

According to an embodiment of the leadframe of the first aspect, the second lead further comprises a second elevation portion alike to the elevation portion of the first lead.

According to an embodiment of the leadframe of the first aspect, the leadframe is a member of a leadframe panel, wherein the leadframe panel comprises an array of m*n leadframes, wherein m and n are integral numbers, wherein the first lead of a leadframe connects to any lead or die pad of an adjacent leadframe via a connection bar perpendicular to the longitudinal direction of the first lead of the leadframe. According to a further example thereof, the connection bar connects the first lead at any one of the following position: the connection portion, the dambar portion of the first lead, or a supporting bar connecting with the end of the external portion of the first lead.

According to an embodiment of the leadframe of the first aspect, the elevation portion of the first lead (12) comprises a height at least no less than 10% if the thickness of the first lead. In different embodiment, depending on different factors of any one of the thickness of the lead, the width of the lead, the hardness of the material of the lead, and/or the different deformation technologies, the height can be no less than 20%, or 30%.

A second aspect of the present disclosure is related to a semiconductor package comprising a leadframe comprising a die pad, a first lead comprising an inner portion and an external portion, wherein the first lead comprises at least one elevation portion extending over a predetermined length in a longitudinal or lateral direction of the first lead, the external portion is configured to be used for external electrical connection, and an encapsulant disposed on the leadframe and the semiconductor die.

According to an embodiment of the semiconductor package of the second aspect, the leadframe further comprises a second lead having an inner portion and an external portion, wherein the external portion is configured to be used for external electrical connection.

According to an embodiment of the semiconductor package of the second aspect, the external portions of the first and the second leads respectively comprise a dambar portion, wherein the elevation of the first lead is arranged on the dambar portion of the first lead.

According to an embodiment of the semiconductor package of the second aspect, the elevation portion is located inside or outside of the encapsulant.

According to an embodiment of the semiconductor package of the second aspect, the first lead is to be used as a drain lead, the second lead is to be used as a source lead, wherein the leadframe further comprises a third lead to be used as a gate lead.

According to an embodiment of the semiconductor package of the second aspect, the first lead is to be used as any one of a gate lead, a source sense lead, a source lead, and an I/O signal lead.

According to an embodiment of the semiconductor package of the second aspect, the semiconductor die is a vertical semiconductor transistor die comprising a first main face and a second main face opposite to the first main face, and a first contact pad disposed on the first main face and connected to the die pad, a second contact pad disposed on the second main face, and a third contact pad disposed on the second main face. According to a further example thereof, the first contact pad is a drain pad, the second contact pad is a source pad, the third contact pad is a gate pad, and the forth contact pad is a source sense pad. In an alternative configuration the first contact pad is the source pad and the second contact pad is the drain pad, which is the so-called source-down configuration. According to further examples thereof, the semiconductor transistor die is an IGBT die or a MOSFET die.

According to an embodiment of the semiconductor package, the semiconductor transistor die is a semiconductor power transistor die. Here, the term “power semiconductor transistor die” may refer to a semiconductor die providing at least one of high voltage blocking or high current-carrying capabilities. A power semiconductor die may be configured for high currents having a maximum current value of a few Amperes, such as e.g. 10 A, 250 A, 600 A, 1000 A, or a maximum current value of up to or even exceeding 1000 A. Similarly, voltages associated with such current values may have values of a few Volts to a few tens or hundreds or even thousands of Volts.

According to an embodiment of the semiconductor package, the encapsulant is disposed so that it embeds the inner portion, but not the connection portion and the external portion of the first lead.

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, “leading”, “trailing”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

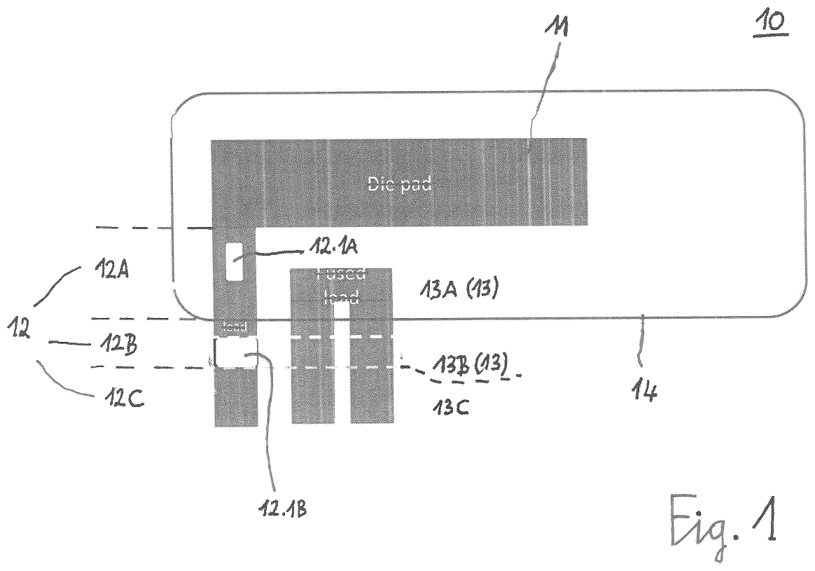

FIG. 1 shows a top view on an example of a leadframe having two elevations on an inner portion and a dambar portion of the first lead, wherein the dambar portion is part of the external portion of the first lead.

More specifically, FIG. 1 shows a leadframe 10 comprising a die pad 11 and a first lead 12 connected with the die pad 11. The first lead 12 comprises an inner portion 12A, a dambar portion 12B, and an external portion 12C is configured to be used for external electrical connection. The first lead 12 further comprises a first elevation portion 12.1A extending over a predetermined length in a longitudinal direction on the inner portion 12A of the first lead 12, and the first lead 12 further comprises a second elevation portion 12.1B extending over a predetermined length in a lateral direction on the dambar portion 12B of the first lead 12. When there is only one lead connects and supports the die pad 11, i.e., there is no another lead or other tie-bar physically connects and supports the die pad 11, having the elevation portion especially on the inner portion of the first lead can significantly improve the stability of the die pad 11 during the later manufacturing processes.

The leadframe 10 further comprises a second lead 13 having an inner portion 13A and an external portion 13B, wherein the external portion 13B is configured to be used for external electrical connection. In the present example the inner portion 13A comprises a fused lateral lead post which can be used for bonding multiple wires or a clip. The second lead 13 can in particular be used as a source lead. Also shown is the outline of an encapsulant 14 which is to be applied to the leadframe 10 in a later step of the fabrication process. It can be seen that the first elevation 12.1A is provided within the encapsulant 14 and the second elevation 12.1B is provided outside of the encapsulant 14. The dambar portion 12B and the external portion 12C together form the external portion of the lead frame according to the first aspect. A skilled person shall understand that although in one embodiment of FIG. 1, there are two elevation sections are shown. However, it should be possible that for other embodiments, only one of the first elevation 12.1A and the second elevation 12.1B exists on the first lead 12. Also a skilled person shall understand that although until now a dambar portion of the external lead is mentioned as an example, but it is possible to make the second elevation portion on the other part of the first lead without overlap with the dambar. This configuration may bring another advantage that the future dambar-cutting process or so-called trimming process will be easier since the dambar portions of all the leads are flat and normal like traditional dambar. Therefore the different position of the section elevation portion on the external lead shall be in the scope of the claims. However the applicant clearly does not want the elevation part to be arranged at an area where in the future soldering process solder will climb up.

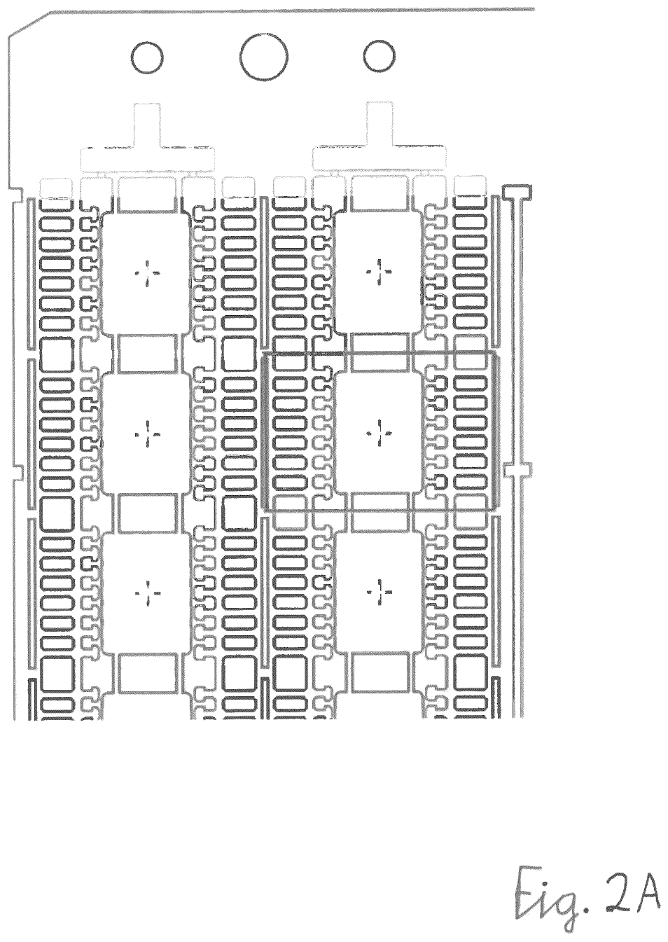

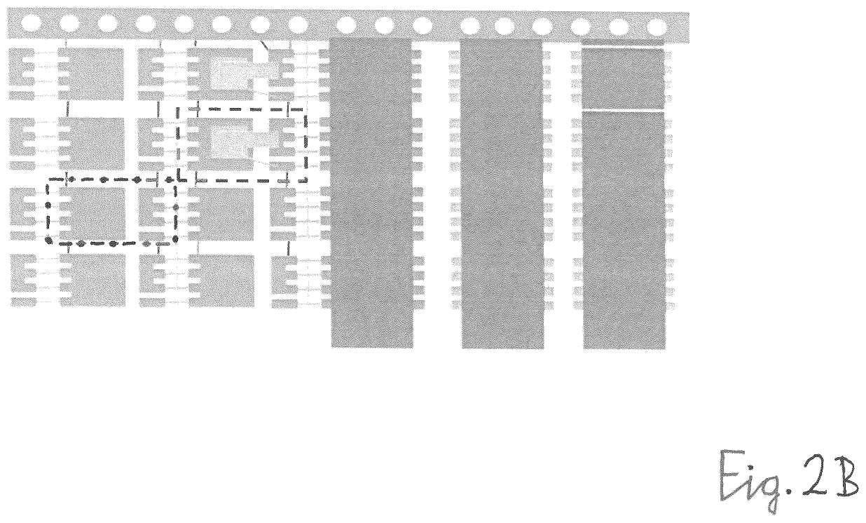

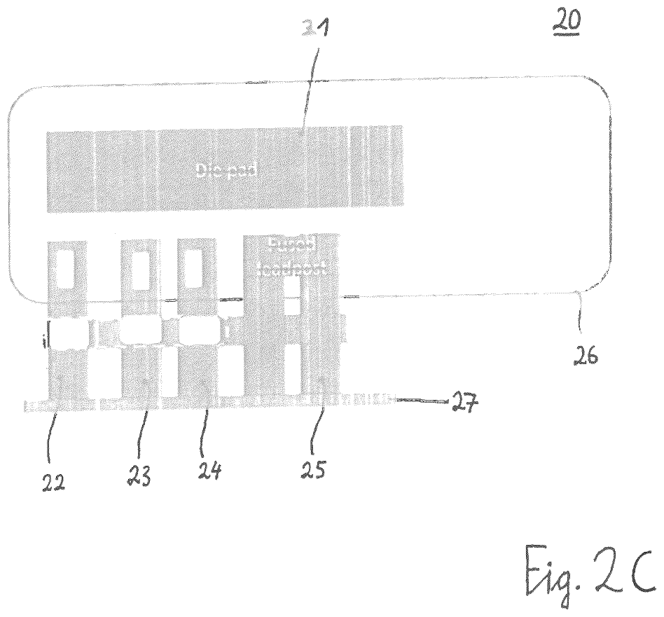

FIG. 2 comprises FIGS. 2A, 2B and 2C and shows two different chocolate bar leadframe comprising m*n individual leadframes (A, B) and a top view on one of the individual leadframes (C).

The examples shown in FIGS. 2A and 2B are special major leadframe panels each containing several single leadframes. In these so-called chocolate bar leadframes several single leadframes are arranged matrix like along several vertical lines, wherein adjacent leadframes are connected by one or more leads with each other via a supporting rail.

FIG. 2A shows one example of such a chocolate bar leadframe panel, which comprises a 2*3 individual leadframes as an example. The area outlined by a solid is an individual leadframe which is the base for a future semiconductor package. It can be seen that all the leads do not physically connect with the die pad, and all the leads in an individual leadframe connect with each other via a dambar and also connect to a supporting rail at the end of these leads. Between two adjacent leadframes, e.g., an upper leadframe and a below leadframe, the lowest lead from the upper leadframe can connect the upmost lead of the below leadframe via a dambar and/or the supporting rail.

FIG. 2B shows another example of a chocolate bar leadframe panel, which comprises 1*4 individual leadframes in the left column, wherein an individual leadframe is outlined by a dash-dotted line as an example. The leadframe panel comprises also 1*4 individual leadframes in the right column wherein the top two leadframes the have finished the die attachment process and wire bonding process, wherein one individual leadframe is outlined in a dashed rectangular as an example. The 3^{rd} column from the left represents the package after a molding process, while the 4^{th} and 5^{th} columns from the left represent the package after a cutting process.

FIG. 2C shows a leadframe 20 that emerged from a chocolate bar leadframe like those shown in FIG. 2A or 2B. The leadframe 20 comprises a die pad 21 and a first lead 22 and further optional leads 23, 24, and 25. In one embodiment, no one of the leads 22 to 25 is physically connected with the die pad 21. Each one of the leads 22 to 25 comprises an inner portion, a dambar portion and an external portion and at least one of the leads 22 to 25 comprises two elevations one of which is provided on the inner portion and the other one of which is provided on the external portion, especially the dambar portion of the external portion of that lead. The inner portion of the lead 25 may comprise a fused lateral lead post as an example which can be used for bonding multiple wires or a clip. Also shown is the outline of an encapsulant 26 which is to be applied to the leadframe 20 in a later step of the fabrication process. It can be seen that first elevations of the leads are provided within the encapsulant 26 and the second elevations of the leads are provided outside of the encapsulant 26. The leads 22 to 25 are connected with a supporting rail 27 which was part of the original chocolate leadframe. A skilled person shall understand it is also possible that only one lead has one elevation on it, either on the inner portion or on the connection portion.

In the present example the leadframe 20 is shown in a stadium in which the elevations in the dambar sections are interconnected between all leads so that in the end product elevations will be provided on all leads in their respective dambar sections. However, it is also possible that the elevation is only provided in the dambar section of the first lead 22. In most chocolate bar leadframe designs, the first lead 22 is a so-called floating lead which means that it has only one end connecting to another component as a support, e.g., the supporting rail 27, wherein another end is vulnerable to vibration because there is no support from another component. The first lead 22 can be very narrow so that the elevation is needed especially there. The first lead 22 is to be used as any one of a drain lead, a gate lead, a source sense lead, a source lead, and an I/O signal lead. Although the supporting rail 27 is shown at the end of each lead and connect all the leads of one leadframe, but a skilled person also should understand that it is possible the supporting rail 27 can be at the position of the dambar of each lead, which means the dambar not only connect all the leads of one leadframe, but also connecting the leads of two adjacent leadframes. For example, the most left lead 22 of one leadframe can connect to a most right lead 25 of an adjacent leadframe, via the supporting rail 27, at the dambar place. A skilled person should understand it is possible to have two supporting rail 27, one at the end of all the leads, while another at the dambar position of all the leads.

FIG. 3 shows a top view on an example of a leadframe having two elevations on a lead which is not connected with the die pad.

More specifically, FIG. 3 shows a leadframe 30 comprising a die pad 31 and a first lead 32 and further leads 33, and 34. The lead 34 is physically separate from the die pad 31, means there is no physical connection between the lead 34 and the die pad 31 in the form of a leadframe. The lead 34 comprises an inner portion and an external portion. The lead 34 comprises two elevations one of which is provided longitudinally on the inner portion and the other one of which is provided laterally on the connection portion in the dambar section. During the later fabrication processes, the lead 34 may be connected by a bond wire to another component like a die or another lead 35. It is possible that only one elevation exists on the inner portion or the connection portion of the lead 34. The elevation on the inner portion is the more important one so that the elevation on the external portion can also be omitted. Furthermore, a skilled person may select the different position for the elevation portion on the inner portion. For a relatively long and narrow first lead 34, the elevation portion maybe preferred to put close to the outline of the encapsulant, e.g., the position of the yellow box, or a place close to the clamping tool used in the later manufacturing process.

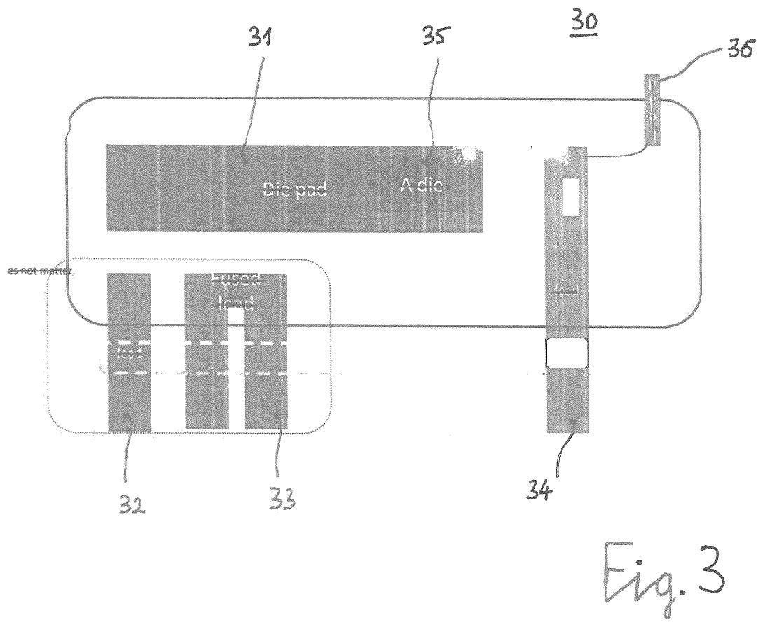

FIG. 4 comprises FIG. 4A and FIG. 4B and shows a top view (A) and a perspective view from the front (B) on an example of a leadframe having a rectangular shaped elevation only on a portion of the tiebar section of the first lead.

More specifically, FIG. 4 shows a leadframe 40 comprising a die pad 44, a first lead 42 connected with the die pad 44, and three further optional leads 43, 44, and 45, wherein the first lead 42 comprises an optional down-set portion 42A, an inner portion 42B, a connection portion 42C, and an external portion 42D. The first lead 42 further comprises an elevation 42.1 on a portion of the inner portion 42B. The elevation 42.1 extends over a predetermined length in a longitudinal direction of the first lead 42.

As can be seen in FIG. 4B, the elevation 42.1 comprises a rectangular shape. It can be produced, for example, by a coining step. The coining step can be performed, for example, by bending or stamping or punching the leadframe from bottom to top. This can be done, for example, with a punch that is used to press against the leadframe from below. The punch has a size corresponding to the desired dimension of the elevation to be created. It is also possible that the coining/stamping/punching is done from the top toward the bottom of the first lead 42.

As further can be seen in FIG. 4, the leadframe 40 optionally comprises further a second lead 43, a third lead 44, and a forth lead 45. As will be seen in further embodiments below, in a semiconductor package to be fabricated including a semiconductor transistor die, the second lead 43 is intended to be used as a source lead, the third lead 44 is intended to be used as a gate lead, and the forth lead 45 is intended to be used as a source/sense lead. Alternatively, in a source-down configuration the second lead can also intended to be used as a drain lead when the semiconductor transistor die is connected with its source pad to the die pad of the leadframe so that the first lead acts as the source lead.

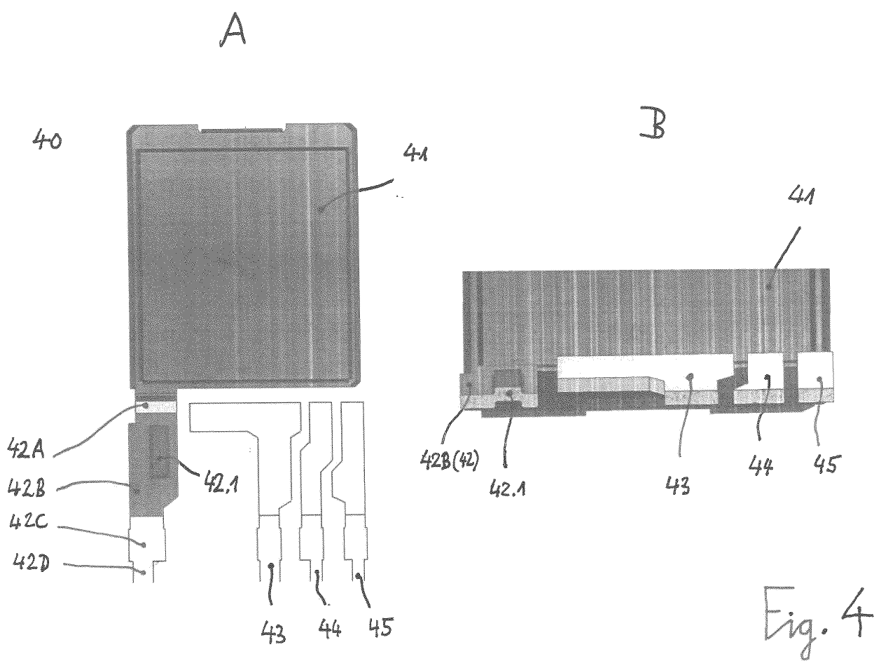

FIG. 5 comprises FIG. 5A to FIG. 5C and shows a top view on a semiconductor package (A), a perspective view (B), and another perspective view (C) on a lead frame contained in the semiconductor package, this example of a leadframe having an elevation rectangular in lateral cross-section and provided on the down-set portion and the complete inner portion of the first lead.

More specifically, FIG. 5 shows a semiconductor package 200 comprising a leadframe 50, a semiconductor transistor die 110 disposed on the die pad 51 of the leadframe 50, a semiconductor diode die 115 also disposed on the die pad 51 of the leadframe 50, and an encapsulant 160 disposed on the leadframe 50 and the semiconductor dies 110 and 150. The encapsulant 160 is indicated here only by a dashed line.

The lead frame 50 comprises the die pad 51, a first lead 52 connected with the die pad 51, and three further optional leads 53, 54, and 55, wherein the first lead 52 comprises an optional down-set portion 52A, an inner portion 52B, a connection portion 52C, and an external portion 52D. The first lead 52 further comprises an elevation 52.1 which in this case is provided on the down-set portion 52A and the complete inner portion 52B, or at least most part, of the first lead 52 and comprises a rectangular shape in a lateral cross-section. In this case, a skilled person also can understand the down-set portion 52A is part of the inner portion 52B. A skilled person should understand that in this description the term “inner portion” is used to illustrate part of the first lead which will be encapsulated inside the mold compound during the later manufacturing processes.

The semiconductor transistor die 110 can be, for example, an IGBT die 110, a MOSFET die, a CoolMOS die, or a SiCMOS die. It is connected to the semiconductor diode die 115 and the second pin 53 by a plurality of bond wires 130. A gate pad and a source/sense pad (both not shown) can be disposed on the upper surface of the semiconductor transistor die 110 and the third pin 54 can be connected to the gate pad by a bond wire and the fourth pin can be connected to the source/sense pad. It is also possible both dies 110 and 115 are same type of dies, so that they are connected in a parallel way for providing a higher current.

Otherwise, as to the second, third and fourth pins 53, 54 and 55 the same may apply as to pins 43, 44 and 45 of FIG. 4, as described above.

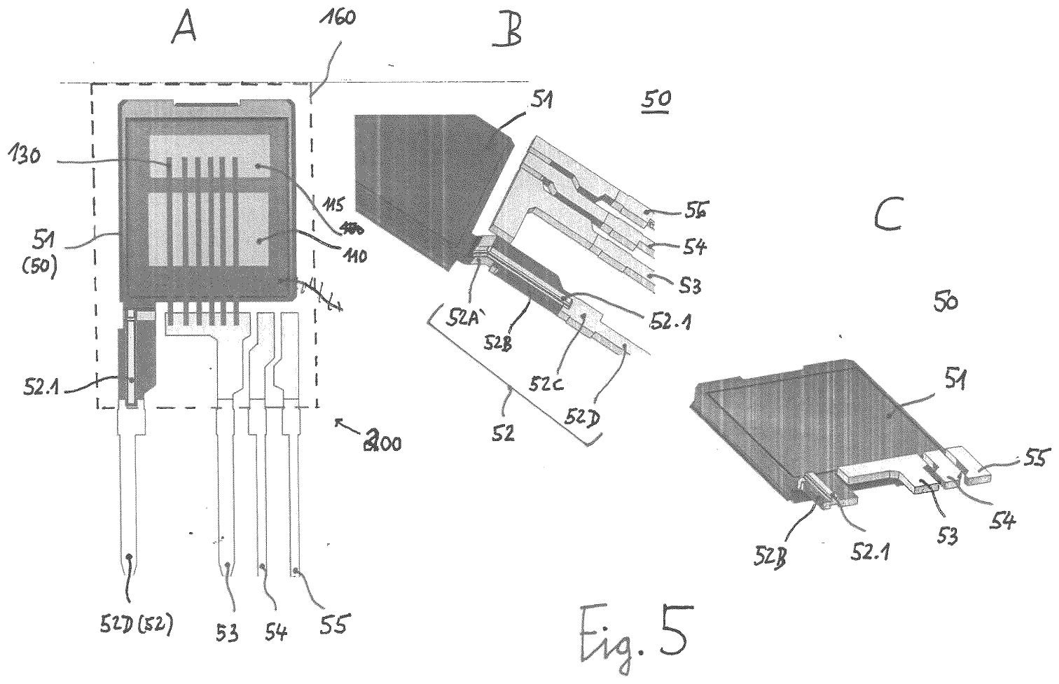

FIG. 6 comprises FIG. 6A and FIG. 6B and shows a top view on a semiconductor package (A) and a perspective view from the front (B) on a leadframe contained in the semiconductor package, this example of a leadframe having a rectangular shaped elevation only on the complete inner portion of the first lead.

More specifically, FIG. 6 shows a semiconductor package 300 comprising a leadframe 60, a semiconductor transistor die 110 disposed on the die pad 61, a semiconductor diode die 115 also dis posed on the die pad 61 of the leadframe 60, and an encapsulant (not shown here) disposed on the leadframe 60 and the semiconductor dies 110 and 115. The encapsulant can be arranged in the same manner as was shown in FIG. 5.

The lead frame 60 comprises the die pad 61, a first lead 62 connected with the die pad 61, and three further optional leads 63, 64, and 65, wherein the first lead 62 comprises an optional down-set portion 62A, an inner portion 62B, a connection portion 62C, and an external portion 62D. The first lead 62 further comprises an elevation 62.1 which in this case is provided on almost the complete inner portion 62B of the first lead 62 and comprises a rectangular shape in a lateral cross-section. Also in some package, the first lead 62 physically connects with the die pad 61 and supports it, but it is possible that the first lead does not have the optional down-set portion 62A and does not physically connect with the die pad. The die pad 61 can be supported by other means, like tie bars (which is not shown here) connecting with the die pad 61 normally in a direction perpendicular to the direction of the first lead, or the full leadframe is arranged in a pre-molded format, so that the die pad 61 is supported by the pre-molded encapsulant.

Otherwise, as to the second, third and fourth pins 63, 64 and 65 and their connections with the contact pads of the semiconductor transistor die 110, the same may apply as to pins 43, 44 and 45 of FIG. 4 and pins 53, 54, and 55 of FIG. 5, as described above.

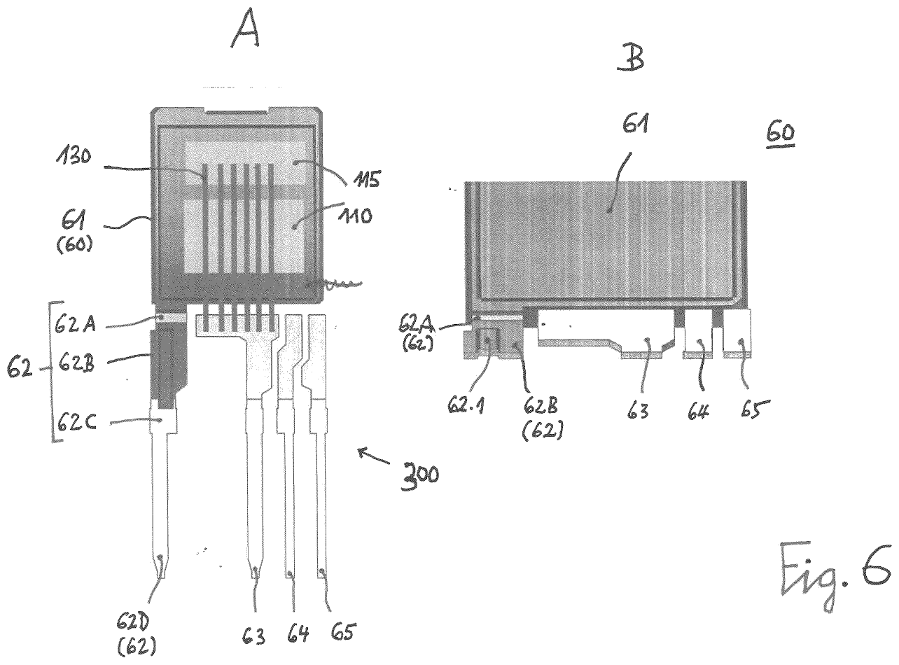

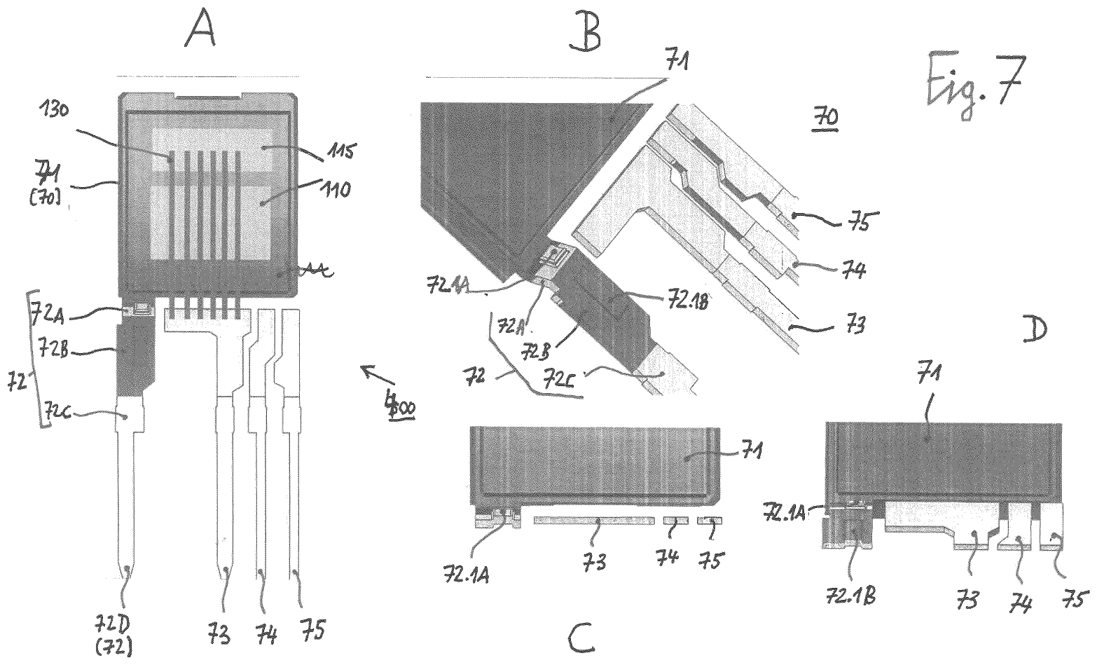

FIG. 7 comprises FIG. 7A to FIG. 7D and shows a top view on a semiconductor package (A), a perspective view (B), a cross-sectional view (C) and another perspective view from the front (D) on a leadframe contained in the semiconductor package, this example of a leadframe having a first rectangular shaped elevation on a portion of the down-set portion and a second elevation on a portion of the inner portion of the first lead.

More specifically, FIG. 7 shows a semiconductor package 400 comprising a leadframe 70, a semiconductor transistor die 110 disposed on the die pad 71 of the leadframe 70, and an encapsulant (not shown) disposed on the leadframe 20 and the semiconductor transistor die 110. The encapsulant can be arranged in the same manner as was shown in FIG. 5.

The lead frame 70 comprises the die pad 71, a first lead 72 connected with the die pad 71, and three further leads 73, 74, and 75, wherein the first lead 72 comprises a down-set portion 72A, an inner portion 72B, a connection portion 72C, and an external portion 72D. The first lead 72 further comprises a first rectangular shaped elevation 72.1A on a portion of the down-set portion 72A of the first lead 72 and a second elevation 72.1B on a portion of the inner portion 72B of the first lead 72. In this case, there are two elevation portions are one the first lead 72 and both of them will be encapsulated inside the semiconductor package. In this case, a skilled person can interpret the entirety of the down-set portion 72A and the inner portion 72B as an inner portion 72B. The term “down-set” portion of the lead is borrowed from its general meaning and use for connecting the first lead to the die pad, so that to support the die pad. It should not be used to limit the meaning of “inner portion” of the embodiments in this description and in the claims.

Otherwise, as to the second, third and fourth pins 73, 74 and 75 and their connections with the contact pads of the semiconductor transistor die 110, the same may apply as to pins 43, 44 and 45 of FIG. 4 and pins 53, 54, and 55 of FIG. 5, as described above.

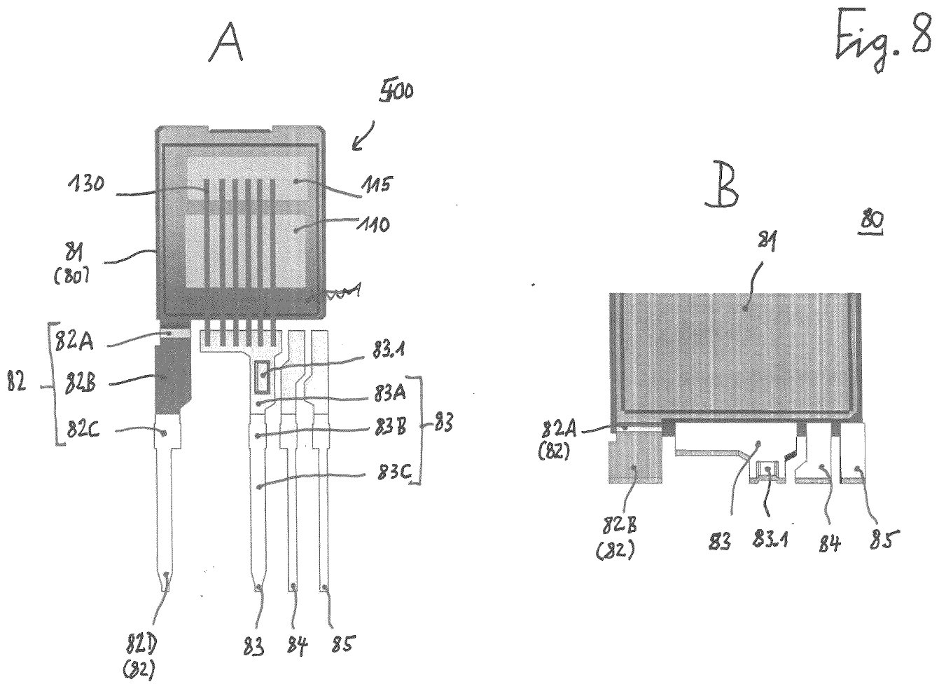

FIG. 8 comprises FIG. 8A and FIG. 8B and shows a top view on a semiconductor package (A) and a perspective view from the front (B) on a leadframe contained in the semiconductor package, this example of a leadframe having a rectangular shaped elevation only on a portion of the second lead.

More specifically, FIG. 8 shows a semiconductor package 500 comprising a leadframe 80, a semiconductor transistor die 110 and a semiconductor diode die 115 both disposed on the die pad 81 of the leadframe 80, and an encapsulant (not shown here) disposed on the leadframe 80 and the semiconductor die 110. The encapsulant can be arranged in the same manner as was shown in FIG. 5.

The lead frame 80 comprises the die pad 81, a first lead 82 connected with the die pad 81, and three further leads 83, 84, and 85, wherein the first lead 82 comprises a down-set portion 82A, an inner portion 82B, a connection portion 82C, and an external portion 82D. The second lead 83 comprises an inner portion 83A, a connection portion 83B, and an external portion 86C. The second lead 83 further comprises an elevation 83.1 which is provided on a portion of the inner portion 836A of the second lead 83 and comprises a rectangular shape in a lateral cross-section.

Otherwise, as to the first, second, third and fourth pins 82, 83, 84, and 85 and their connections with the contact pads of the semiconductor transistor die 110, the same may apply as to pins 42, 43, 44 and 45 of FIG. 4 and pins 22, 23, 24, and 25 of FIG. 5, as described above.

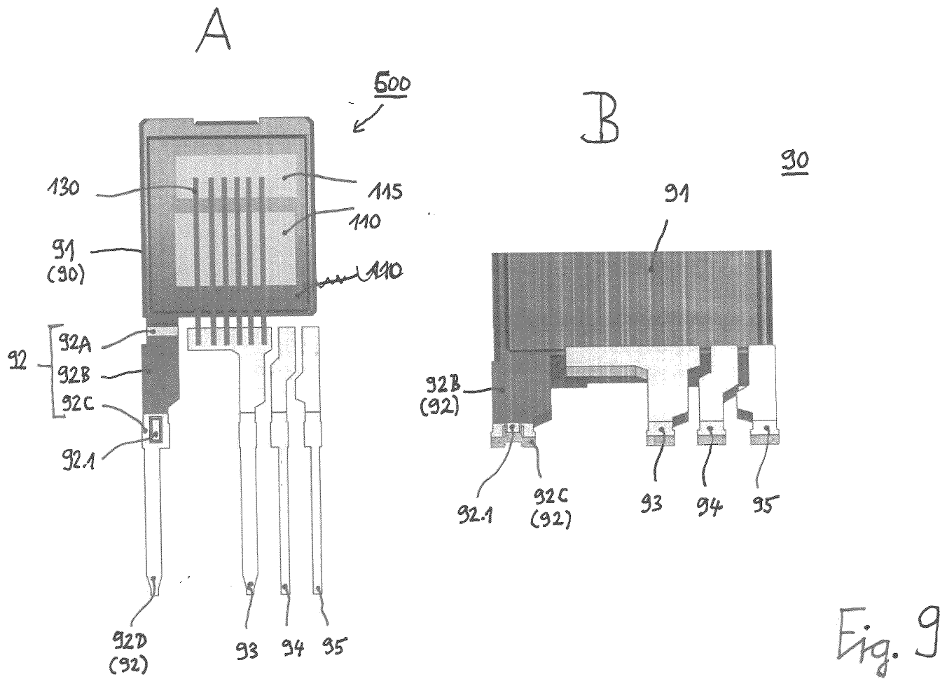

FIG. 9 comprises FIG. 9A and FIG. 9B and shows a top view on a semiconductor package (A) and a perspective view from the front (B) on a leadframe contained in the semiconductor package, this example of a leadframe having a rectangular shaped elevation only on a portion of the dambar section of the first lead.

More specifically, FIG. 9 shows a semiconductor package 600 comprising a leadframe 90, a semiconductor transistor die 110 and a semiconductor diode die 115 both disposed on the die pad 91 of the leadframe 90, and an encapsulant (not shown here) disposed on the leadframe 90 and the semiconductor dies 110 and 115. The encapsulant can be arranged in the same manner as was shown in FIG. 5.

The lead frame 90 comprises the die pad 91, a first lead 92 connected with the die pad 91, and three further leads 93, 94, and 95, wherein the first lead 92 comprises a down-set portion 92A, an inner portion 92B, a connection portion 92C, and an external portion 92D. The first lead 92 further comprises an elevation 92.1 which in this case is provided on a portion of the connection portion 92C of the first lead 92 and comprises a rectangular shape in a lateral cross-section.

Otherwise, as to the second, third and fourth pins 93, 94 and 95 and their connections with the contact pads of the semiconductor transistor die 110, the same may apply as to pins 43, 44 and 45 of FIG. 4 and pins 53, 54, and 55 of FIG. 5, as described above.

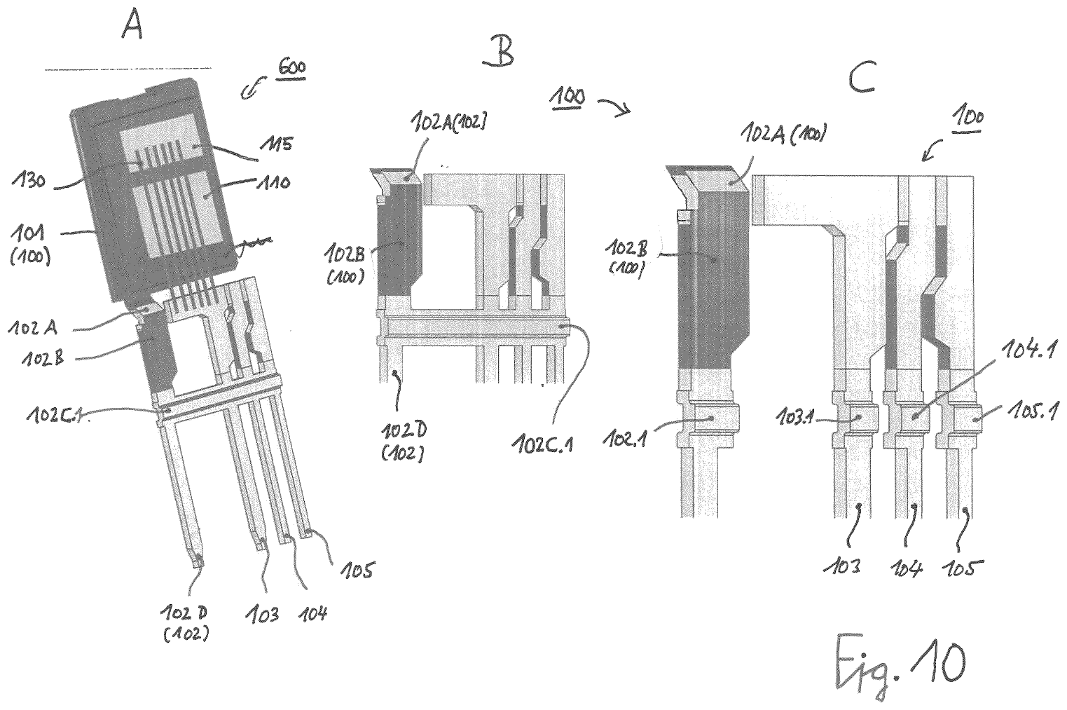

FIG. 10 comprises FIG. 10A to FIG. 10C and shows a top view on an intermediate product of the semiconductor package fabrication (A), a perspective view from the side (B) on a portion of the leadframe contained in the intermediate product, and an enlarged perspective view from the side (C) on the portion of the finished leadframe, this example of a leadframe having a rectangular shaped elevation extending laterally on the dambar section of the first lead.

More specifically, FIG. 10 shows a semiconductor package 600 comprising a leadframe 100, a semiconductor transistor die 110 and a semiconductor diode die 115 both disposed on the die pad 101 of the leadframe 100, and an encapsulant (not shown here) disposed on the leadframe 100 and the semiconductor dies 110 and 115. The encapsulant can be arranged in the same manner as was shown in FIG. 4.

The lead frame 100 comprises the die pad 101, a first lead 102 connected with the die pad 101, and three further leads 103, 104, and 105, wherein the first lead 102 comprises a down-set portion 102A, an inner portion 102B, a connection portion 102C, and an external portion 102D. The first lead 102 further comprises an elevation 102.1 which is provided on a portion of the connection portion 102C of the first lead 102 and comprises a rectangular shape in a lateral cross-section. In this case also the other three pins 103, 104, and 105 comprise respective elevations 103.1, 103.1, and 103.1 which are also disposed on their respective connection portions 103B, 104B, 105B. FIGS. 10A and 10B show an intermediate product of the fabrication process in which the elevations 102.1, 103.1, 104.1, and 105.1 of all four pins 102, 103, 104, and 105 are interconnected by a bar 102C.1. In a later step the connections are removed to result in the structure as shown in FIG. 10C.

Otherwise, as to the second, third and fourth pins 103, 104 and 105 and their connections with the contact pads of the semiconductor transistor die 110, the same may apply as to pins 43, 44 and 45 of FIG. 4 and pins 53, 54, and 55 of FIG. 5, as described above.

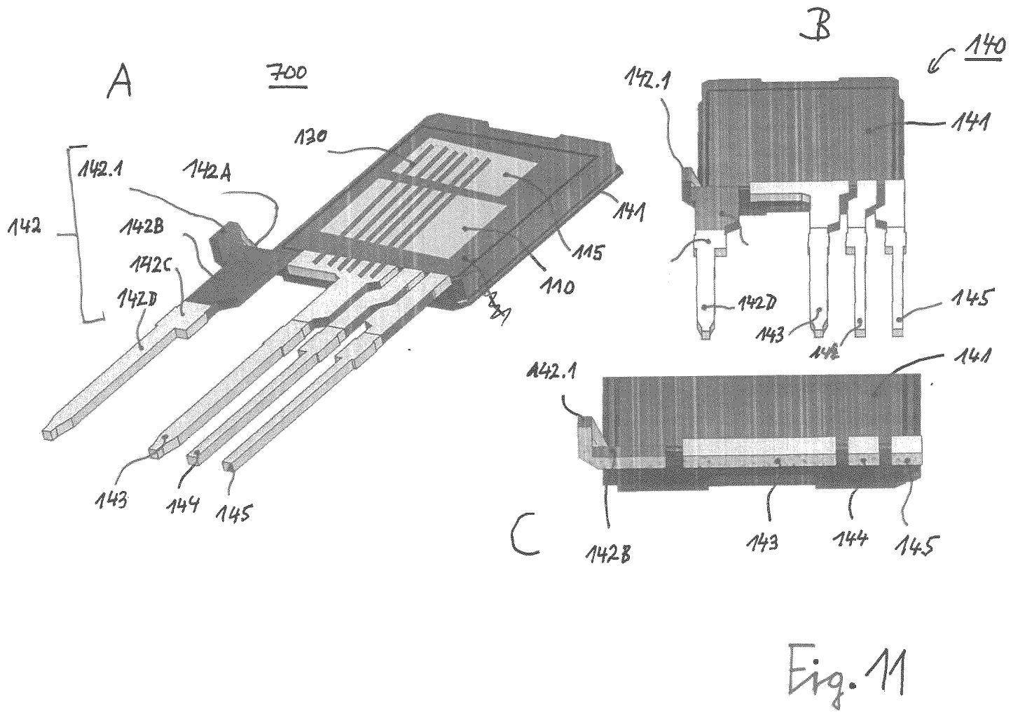

FIG. 11 comprises FIG. 11A to FIG. 11C and shows a perspective view on a semiconductor package (A), a perspective view from the front (B), and another perspective view from slightly below (C) on a lead frame contained in the semiconductor package, this example of a leadframe having a bent up member on an edge portion of the inner portion.

More specifically, FIG. 11 shows a semiconductor package 700 comprising a leadframe 140, a semiconductor transistor die 110 and a semiconductor diode die 115 both disposed on the die pad 141 of the leadframe 140, and an encapsulant (not shown here) disposed on the leadframe 140 and the semiconductor die 110. The encapsulant can be arranged in the same manner as was shown in FIG. 1.

The lead frame 140 comprises the die pad 141, a first lead 142 connected with the die pad 141, and three further leads 143, 144, and 145, wherein the first lead 142 comprises a down-set portion 142A, an inner portion 142B, a connection portion 142C, and an external portion 142D. The first lead 142 further comprises a bent up member 142.1 on an edge portion of the inner portion 142B. The bent up member 142.1 can be a flat extension of the inner portion 142B at the beginning of the fabrication process which extension can be bent up later to result in the structure as shown in FIG. 11.

Otherwise, as to the second, third and fourth pins 143, 144 and 155 and their connections with the contact pads of the semiconductor transistor die 110, the same may apply as to pins 43, 44 and 45 of FIG. 1 and pins 53, 54, and 55 of FIG. 5, as described above.

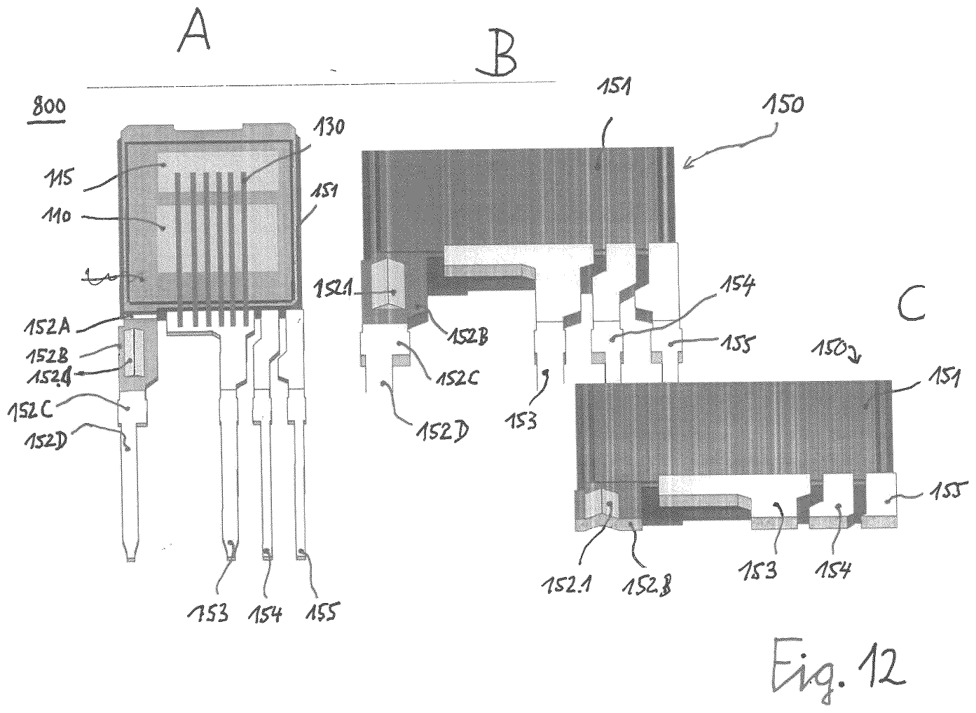

FIG. 12 comprises FIG. 12A to FIG. 12C and shows a top view on a semiconductor package (A), a perspective view from the front of a leadframe contained in the semiconductor package (B), and another perspective view (C) from the front on a portion of the lead frame, this example of a leadframe having a V shaped elevation on a portion of the inner portion of the first lead.

More specifically, FIG. 12 shows a semiconductor package 800 comprising a leadframe 150, a semiconductor die 110 disposed on the die pad 151 of the leadframe 150, and an encapsulant (not shown here) disposed on the leadframe 150 and the semiconductor die 110. The encapsulant can be arranged in the same manner as was shown in FIG. 1.

The lead frame 150 comprises the die pad 151, a first lead 152 connected with the die pad 151, and three further leads 153, 154, and 155, wherein the first lead 152 comprises a down-set portion 152A, an inner portion 152B, a connection portion 152C, and an external portion 152D. The first lead 152 further comprises an elevation 152.1 which in this case is provided on a portion of the inner portion 152B of the first lead 152 and comprises a V shape in a lateral cross-section.

Otherwise, as to the second, third and fourth pins 153, 154 and 155 and their connections with the contact pads of the semiconductor transistor die 110, the same may apply as to pins 43, 44 and 55 of FIG. 1 and pins 53, 54, and 55 of FIG. 5, as described above.

In all the embodiments, the connection between the two dies or between the die and the second/third/fourth lead should not be used to limit the protection of the present invention, since these connection does not impact the elevation structure on at least one lead of the leadframe or the future semiconductor package. Further, although in the embodiments of FIGS. 1 to 12, the terms of “connection portion” and the “external portion” are used. But the main purpose is for the ease of describing the position of the elevation structures when they are arranged at the dambar position of each lead. A skilled person can interpret the connection portion and the external portion of the first lead as a whole as the external portion of the first lead, which is outside of the encapsulant of the final semiconductor package, corresponding to the inner portion of the first lead which is inside the encapsulant of the package. For those packages that do not have a dam bar between their leads, there is no “connection portion” on these leads, and therefore there is no need for the elevation structure on the connection portion of the first lead.

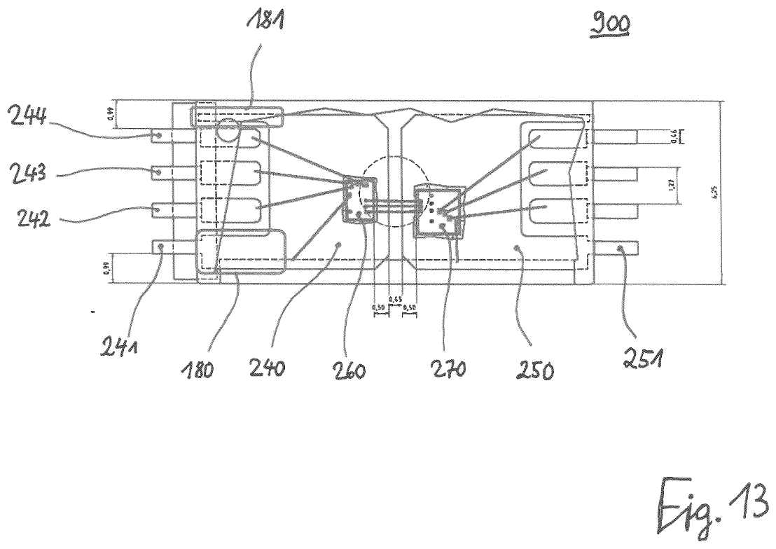

FIG. 13 shows a top view on a gate driver die, wherein the preferred locations for the placement of the elevations are shown.

More specifically, FIG. 13 shows a semiconductor package 900 comprising a leadframe, a first die pad 240 and a second die pad 250 and a first semiconductor die 260 and a second semiconductor die 270, the first semiconductor die 260 disposed on the first die pad 240 and the second semiconductor die 270 disposed on the second die pad 250, and an encapsulant (not shown here) disposed on the leadframe and the semiconductor dies 260 and 270. The encapsulant can be arranged in the same manner as was shown in FIG. 2.

The leadframe further comprises a first lead 241 connected with the die pad 240, and three further leads 242, 243, and 244 which are connected by bond wires with contact pads of the first semiconductor die 260. A lead 251 is connected with the second die pad 250. Also drawn in FIG. 13 are two rectangular outlines 280 and 281, which indicate two preferred locations in the semiconductor package 900 where elevations could be applied. The below outline 180 depicts the area where the first lead 241 connecting with the die pad, and the elevation portion can be arranged on there. In this case, the first lead 241 also functions as a connection to an external component, like PCB or other packages/passive components. The top outline 181 depicts a dummy lead or dummy tie bar, which is designed to improve the stability of the die pad 240 during the manufacturing processes and will be cut after molding process so that it will not substantially protrude from the encapsulant. That dummy tie bar does not have any electrical connection functionality. Arranging an elevation structure on the dummy lead also helps to improve the stability of the die pad. If the elevation on the first lead 241 works well, a skilled person can understand there is no need for the dummy lead/tie bar, so that the die pads 240/250 can be simplified.

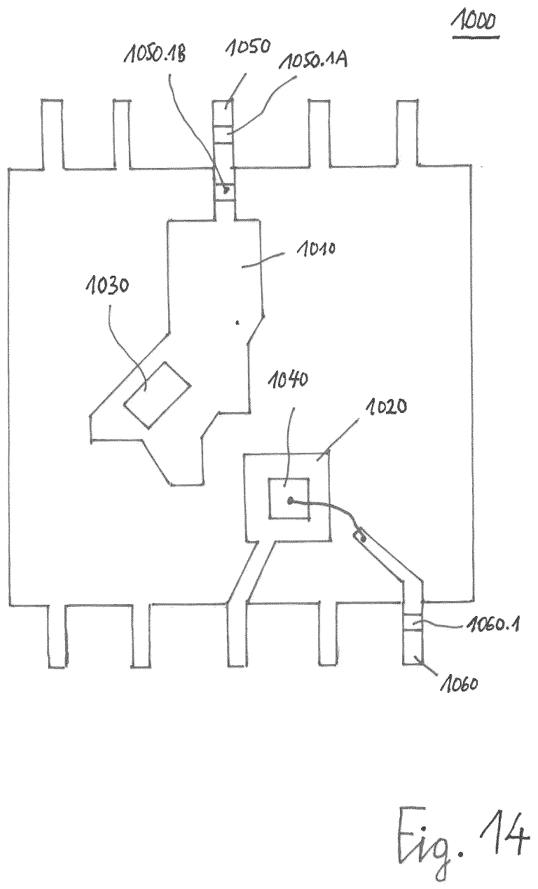

FIG. 14 shows a top view on section of a typical IPM module in which elevations are provided on particular leads.

More specifically, FIG. 14 shows a portion of a semiconductor package 1000 comprising a first die pad 1010, a second die pad 1020, a first semiconductor die 1030 disposed on the first die pad 1010, and a second semiconductor die 1040 disposed on the second die pad 1020. The semiconductor package 1000 is connected with a plurality of leads wherein a first lead 1050 is connected with the first die pad 1010, and a second lead 1060 is connected with the second die pad 1020. Since the first die pad 1010 is connected with only the first 1050, the first lead 1050 and optionally the die pad 1010 are vulnerable to vibration and therefore provided with elevations 1050.1A and 1050.1B on the first lead 1050. A first elevation 1050.1A is disposed on an external portion of the first lead 150 and second elevation 1050.1B is disposed on an inner portion of the first lead 1050. Likewise the second lead 1060 is connected with the second semiconductor die 1040 via a bond wire, and is provided with an elevation 1060.1 on an external portion thereof. It is also possible an elevation structure arranged on the inner portion of the lead 1060.

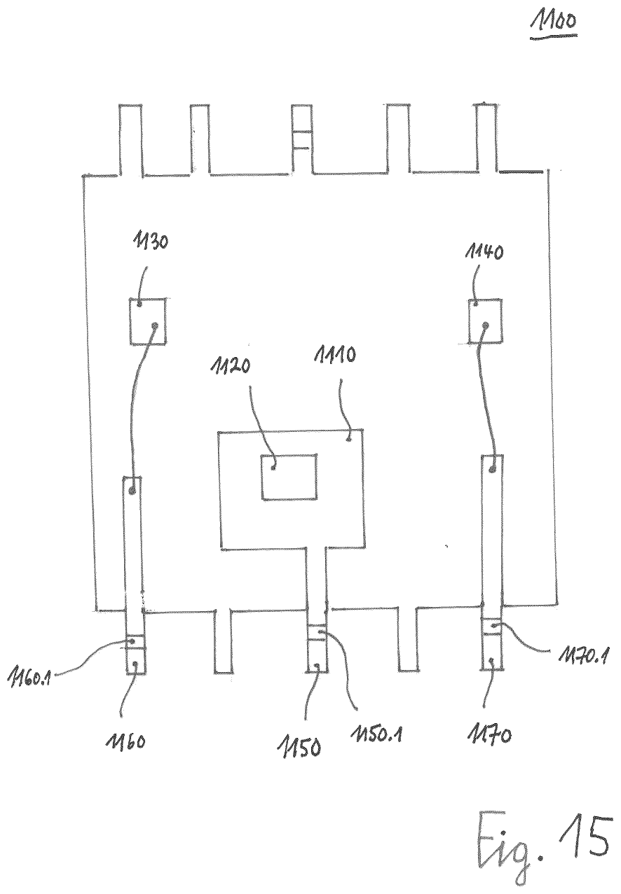

FIG. 15 shows a top view on section of a typical IPM module (intelligent power module) in which elevations are provided on particular leads.

More specifically, FIG. 15 shows a portion of a semiconductor package 1100 comprising a die pad 1110, a semiconductor die 1120 disposed on the die pad 1110, and contact regions 1130 and 1140. The semiconductor package 1100 is connected with a plurality of leads wherein a first lead 1150 is connected with the die pad 1110, a second lead 1160 is connected with a first contact region 1130 via a bond wire, and a third lead 1170 is connected with a second contact region 1140 via a bond wire. Since the first to third leads 1150 to 1170 are deemed vulnerable to vibration, they are therefore provided with respective elevations 1150.1, 1160.1 and 1170.1, all of them disposed on respective external portions of the leads 1050 to 1070. After reading the previous embodiments, a skilled person shall understand that these elevations also can be arranged on the corresponding portion of these leads inside the encapsulant or the case of IPM products.

### EXAMPLES

In the following specific examples of the present disclosure are described.

Example 1 is a leadframe comprising a die pad, a first lead comprising an inner portion and an external portion, wherein the first lead comprises at least one elevation portion extending over a predetermined length in a longitudinal or lateral direction of the first lead, wherein the external portion is configured to be used for external electrical connection.

Example 2 is a leadframe according to Example 1,
further comprising a second lead having an inner portion and an external portion, wherein the external portion is configured to be used for external electrical connection.

Example 3 is a leadframe according to Example 1 or 2, wherein the elevation is produced by a deformation of the first lead, in particular by a coining exerted in a direction perpendicular to the longitudinal direction of the first lead.

Example 4 is a leadframe according to Example 3,
wherein the elevation portion is arranged on the inner portion, wherein the inner portion is to be embedded into an encapsulant.

Example 5 is a leadframe according to any one of the preceding Examples, wherein the external portions of the first and the second leads respectively comprise a dambar portion, wherein the elevation of the first lead is arranged on the dambar portion of the first lead.

Example 6 is a leadframe according to any one of the preceding Examples, wherein the first lead is physically connected to the die pad.

Example 7 is a leadframe according to Example 6, wherein the inner portion comprises a down-set portion.

Example 8 is a leadframe according to any one of the preceding Examples, wherein the inner portion of the first lead is not physically connected to the die pad.

Example 9 is a leadframe according to Example 8, wherein the inner portion is configured to be connected to a bonding wire or a passive component.

Example 10 is a leadframe according to any one of the preceding Examples, wherein the elevation is provided on both the inner portion and the dambar portion.

Example 11 is a leadframe according to any one of the preceding Examples, wherein the elevation comprises any one of
a rectangular shape in a lateral cross section,
a V shape in a lateral cross section, and
a bent up member on an edge of the inner portion.

Example 12 is a leadframe according to any one of the preceding Examples, wherein the second lead further comprises a second elevation portion alike to the elevation portion of the first lead.

Example 13 is a leadframe according to any one of the preceding Examples, wherein the leadframe is a member of a leadframe panel, wherein the leadframe panel comprises an array of m*n leadframes, wherein m and n are integral numbers, wherein the first lead of a leadframe connects to any lead or die pad of an adjacent leadframe via a connection bar perpendicular to the longitudinal direction of the first lead of the leadframe.

Example 14 is a leadframe according to Example 13, wherein the connection bar connects the first lead at any one of the following position: the connection portion, the dambar portion of the first lead, or a supporting bar connecting with the end of the external portion of the first lead.

Example 15 is a leadframe according to any one of the preceding Examples, wherein the elevation portion of the first lead comprises a height in a range of more than 10%, or more than 20%, or more than 30% of the thickness of the first lead.

Example 16 is a semiconductor package comprising a leadframe comprising a die pad, a first lead comprising an inner portion and an external portion, wherein the first lead comprises at least one elevation portion extending over a predetermined length in a longitudinal or lateral direction of the first lead, the external portion is configured to be used for external electrical connection, and an encapsulant disposed on the leadframe and the semiconductor die.

Example 17 is a semiconductor package according to Example 16, further comprising the leadframe comprising a second lead having an inner portion and an external portion, wherein the external portion is configured to be used for external electrical connection.

Example 18 is a semiconductor package according to Examples 16 or 17, wherein the elevation portion is located inside or outside of the encapsulant.

Example 19 is a semiconductor package according to any one of Examples 16 to 18, wherein the external portions of the first and the second leads respectively comprise a dambar portion, wherein the elevation of the first lead is arranged on the dambar portion of the first lead.

Example 20 is a semiconductor package according to any one of Examples 16 to 19, wherein the first lead is to be used as a drain lead, the second lead is to be used as a source lead, wherein the leadframe further comprises a third lead to be used as a gate lead.

Example 21 is a semiconductor package according to any one of Examples 16 to 20, wherein the first lead is to be used as any one of a gate lead, a source sense lead, a source lead, and an I/O signal lead.

Example 22 is a semiconductor package according to any one of Examples 16 to 21, wherein the semiconductor die is a vertical semiconductor transistor die comprising a first main face and a second main face opposite to the first main face, and a first contact pad disposed on the first main face and connected to the die pad, a second contact pad disposed on the second main face, and a third contact pad disposed on the second main face.

Example 23 is a semiconductor package according to any one of Examples 16 to 22, wherein the vertical semiconductor transistor die comprises a forth contact pad disposed on the second main face.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A leadframe, comprising:
a die pad;
a first lead comprising an inner portion and an external portion, wherein the first lead comprises at least one elevation portion extending over a predetermined length in a longitudinal or lateral direction of the first lead, wherein the external portion is configured to be used for external electrical connection.

2. The leadframe according to claim 1, further comprising
a second lead having an inner portion and an external portion, wherein the external portion is configured to be used for external electrical connection.

3. The leadframe according to claim 1, wherein
the elevation is produced by a deformation of the first lead, in particular by a coining exerted in a direction perpendicular to the longitudinal direction of the first lead.

4. The leadframe according to claim 3, wherein the elevation portion is arranged on the inner portion, wherein the inner portion is to be embedded into an encapsulant.

5. The leadframe according to claim 1, wherein the external portions of the first and the second leads respectively comprise a dambar portion, wherein the elevation of the first lead is arranged on the dambar portion of the first lead.

6. The leadframe according to claim 1, wherein
the first lead is physically connected to the die pad.

7. The leadframe according to claim 6, wherein
the inner portion comprises a down-set portion.

8. The leadframe according to claim 1, wherein the inner portion of the first lead is not physically connected to the die pad.

9. The leadframe according to claim 8, wherein
the inner portion is configured to be connected to a bonding wire or a passive component.

10. The leadframe according to claim 1, wherein the elevation is provided on both the inner portion and the dambar portion.

11. The leadframe according to claim 1, wherein the elevation comprises any one of
a rectangular shape in a lateral cross section,
a V shape in a lateral cross section, and
a bent up member on an edge of the inner portion.

12. The leadframe according to claim 1, wherein the second lead further comprises a second elevation portion alike to the elevation portion of the first lead.

13. The leadframe according to claim 1, wherein
the leadframe is a member of a leadframe panel, wherein the leadframe panel comprises an array of m*n leadframes, wherein m and n are integral numbers, wherein the first lead of a leadframe connects to any lead or die pad of an adjacent leadframe via a connection bar perpendicular to the longitudinal direction of the first lead of the leadframe.

14. The leadframe according to claim 13, wherein
the connection bar connects the first lead at any one of the following position: the connection portion, the dambar portion of the first lead, or a supporting bar connecting with the end of the external portion of the first lead.

15. The leadframe according to claim 1, wherein
the elevation portion of the first lead comprises a height in a range of more than 10%, or more than 20%, or more than 30% of the thickness of the first lead.

16. A semiconductor package, comprising
a leadframe comprising a die pad, a first lead comprising an inner portion and an external portion, wherein the first lead comprises at least one elevation portion extending over a predetermined length in a longitudinal or lateral direction of the first lead, the external portion is configured to be used for external electrical connection; and
an encapsulant disposed on the leadframe and the semiconductor die.

17. The semiconductor package according to claim 16, further comprising
the leadframe comprising a second lead having an inner portion and an external portion, wherein the external portion is configured to be used for external electrical connection.

18. The semiconductor package according to claim 16, wherein
the elevation portion is located inside or outside of the encapsulant.

19. The semiconductor package according to claim 16, wherein the external portions of the first and the second leads respectively comprise a dambar portion, wherein the elevation of the first lead is arranged on the dambar portion of the first lead.

20. The semiconductor package according to claim 16, wherein
the first lead is to be used as a drain lead, the second lead is to be used as a source lead, wherein the leadframe further comprises a third lead to be used as a gate lead.

21. The semiconductor package according to claim 16, wherein
the first lead is to be used as any one of a gate lead, a source sense lead, a source lead, and an I/O signal lead.

22. The semiconductor package according to according to claim 16, wherein
the semiconductor die is a vertical semiconductor transistor die comprising a first main face and a second main face opposite to the first main face, and a first contact pad disposed on the first main face and connected to the die pad, a second contact pad disposed on the second main face, and a third contact pad disposed on the second main face.

23. The semiconductor package according to claim 22, wherein
the vertical semiconductor transistor die comprises a forth contact pad disposed on the second main face.
